(19) United States
(12) Patent Application Publication
(10) Pub. No.: US 2026/0362640 A1
(43) Pub. Date: Nov. 12, 2026

(54) MOTHERBOARD COOLING SYSTEM AND SERVER

(71) Applicants: Inventec (Pudong) Technology Corporation, Shanghai (CN); INVENTEC CORPORATION, Taipei (TW)

(72) Inventor: Guoping Wu, Shanghai (CN)

(21) Appl. No.: 19/266,195

(22) Filed: Jul. 11, 2025

(30) Foreign Application Priority Data
May 9, 2025 (CN) 202510599997.5

(51) Int. Cl. H05K 7/20

(52) U.S. Cl. CPC H05K 7/20263; H05K 7/20254; H05K 7/20772; H05K 7/20809

(57) ABSTRACT

A motherboard cooling system includes a cooling plate structure, a heat diffusion structure, a heat dissipation structure and a connection structure. The cooling plate structure is in thermal contact with the CPU, and the coolant flows through the cooling plate structure to dissipate heat of the CPU. The heat diffusion structure is in thermal contact with the DIMM, and the heat diffusion structure is also in thermal contact with the cooling plate structure. Heat generated by the DIMM reaches the cooling plate structure through the heat diffusion structure. The heat dissipation structure is connected to the cooling plate structure, and the heat generated by the CPU and the DIMM is dissipated through the heat dissipation structure. The connection structure is connected to the cooling plate structure and the heat dissipation structure respectively. The connection structure, the cooling plate structure and the heat dissipation structure cooperatively form a circulation loop.

### CROSS REFERENCES TO RELATED APPLICATION

This application claims priority to Chinese patent application No. 202510599997.5, filed on May 9, 2025, entitled “MOTHERBOARD COOLING SYSTEM AND CHASSIS”, the content of which is hereby incorporated by reference in its entirety.

### TECHNICAL FIELD

The present disclosure relates to the technical field of server, and in particular to a motherboard cooling system and a server.

### BACKGROUND

As the power consumption of components in servers continues to increase, the heat dissipation of high-power devices in servers becomes particularly difficult. Especially for the heat dissipation of CPU (Central Processing Unit) modules and DIMM (Dual In-line Memory Module), the corresponding power consumption and heat flux density of the two are gradually increasing. Therefore, the heat dissipation of the air cooling system in traditional technology cannot meet the increasingly high heat dissipation requirements.

In related technologies, the heat dissipation of CPU and DIMM is usually carried out through liquid cooling systems respectively. However, there are many liquid cooling pipes and interfaces in the heat dissipation liquid cooling systems for CPU and DIMM, which are very prone to system leakage, and increase the cost of heat dissipation.

### SUMMARY

Accordingly, it is necessary to provide a motherboard cooling system and server to address the problem that the existing heat dissipation method is prone to system leakage.

A motherboard cooling system includes a cooling plate structure, a heat diffusion structure, a heat dissipation structure and a connection structure. The cooling plate structure is in thermal contact with a CPU, and a coolant flowing through the cooling plate structure to dissipate heat of the CPU. The heat diffusion structure is in thermal contact with a DIMM and the cooling plate structure, and heat generated by the DIMM reaching the cooling plate structure through the heat diffusion structure. The heat dissipation structure is connected to the cooling plate structure, and the heat generated by the CPU and the DIMM are dissipated through the heat dissipation structure. The connection structure is connected to the cooling plate structure and the heat dissipation structure respectively, and the connection structure, the cooling plate structure and the heat dissipation structure cooperatively form a circulation loop.

A server includes a chassis and the aforementioned motherboard cooling system. The motherboard cooling system is arranged in the chassis to cool the CPU and the DIMM.

These and other objects, advantages, purposes and features will become apparent upon review of the following specification in conjunction with the drawings.

### BRIEF DESCRIPTION OF THE DRAWINGS

To illustrate the technical solutions according to the embodiments of the present invention or in the prior art more clearly, the accompanying drawings for describing the embodiments or the prior art are introduced briefly in the following. Apparently, the accompanying drawings in the following description are only some embodiments of the present invention, and persons of ordinary skill in the art can derive other drawings from the accompanying drawings without creative efforts.

FIG. 1 is a perspective view of a motherboard cooling system according to an embodiment of the present disclosure.

FIG. 2 is a perspective view of the motherboard cooling system of FIG. 1 viewed from a second aspect.

FIG. 3 is a top view of the motherboard cooling system of FIG. 1.

FIG. 4 is a perspective view of a heat diffusion structure of FIG. 1.

FIG. 5 is a cross-sectional view of a cooling plate structure of FIG. 1.

### DESCRIPTION OF THE REFERENCE NUMERALS

100: cooling plate structure; 110: plate body; 120: fin;
200: CPU;
300: heat diffusion structure; 310: heat diffusion main body; 311: first main body; 312: second main body; 320: heat conduction portion; 321: heat pipe; 322: second heat conduction layer;
400: DIMM;
500: heat dissipation structure; 510: pump body; 520: heat sink;
600: connection structure;
700: first heat conduction layer.

### DETAILED DESCRIPTION OF THE EMBODIMENTS

In order to make the aforementioned objects, features and advantages of the present disclosure more clearly understood, the specific embodiments of the present disclosure will be described in detail below with reference to the accompanying drawings. In the following description, numerous specific details are set forth in order to provide a thorough understanding of the present disclosure. However, the present disclosure can be implemented in many other ways different from those described herein, and those skilled in the art can make similar improvements without departing from the connotation of the present disclosure. Therefore, the present disclosure is not limited by the specific embodiments disclosed below.

In the description of the present disclosure, it should be understood that if the terms “center”, “longitudinal”, “lateral”, “length”, “width”, “thickness”, “up”, “down”, “front”, “back”, “left”, “right”, “vertical”, “horizontal”, “top”, “bottom”, “inside”, “outside”, “clockwise”, “counterclockwise”, “axial”, “radial”, “circumferential”, etc. appear, the orientation or position relationship indicated by these terms is based on the orientation or position relationship shown in the drawings, which is only for the convenience of describing the present disclosure and simplifying the description, rather than indicating or implying that the device or element referred to must have a specific orientation, be constructed and operated in a specific orientation, and therefore cannot be understood as limiting the present disclosure.

In addition, if the terms “first” and “second” appear, these terms are only used for descriptive purposes and cannot be understood as indicating or implying relative importance or implicitly indicating the number of technical features indicated. Thus, the features defined as “first” and “second” may explicitly or implicitly include at least one of the features. In the description of the present disclosure, if the term “a plurality of” appears, the meaning of “a plurality of” is at least two, such as two, three, etc., unless otherwise clearly and specifically defined.

In the present disclosure, unless otherwise clearly specified and limited, if the terms “mount”, “connect together”, “connect”, “fix”, etc. appear, these terms should be understood in a broad sense. For example, it can be a fixed connection, a detachable connection, or an integrated connection; it can be a mechanical connection or an electrical connection; it can be a direct connection or an indirect connection through an intermediate medium, it can be the internal connection of two elements or the interaction relationship between two elements, unless otherwise clearly defined. For ordinary technical people in the art, the specific meaning of the aforementioned terms in the present disclosure can be understood according to the specific circumstances.

In the present disclosure, unless otherwise clearly specified and limited, if there is a description that a first feature is “on” or “below” a second feature, etc., or similar description, it may mean that the first feature and second feature are in direct contact, or the first feature and second feature are in indirect contact through an intermediate medium. Also, the first feature is “above”, “over” and “on” the second feature may mean that the first feature is directly above or obliquely above the second feature, or simply means that the first feature has a higher level than the second feature. The first feature being “below”, “beneath” and “under” the second feature may mean that the first feature is directly or obliquely below the second feature, or simply means that the first feature has a lower level than the second feature.

It should be noted that if an element is referred to as being “fixed to” or “disposed on” another element, it may be directly on the other element or there may be a central element. If an element is considered to be “connected to” another element, it may be directly connected to the other element or there may be a central element at the same time. If present, the terms “vertical”, “horizontal”, “upper”, “lower”, “left”, “right” and similar expressions used in the present disclosure are only for illustrative purposes and do not represent the only implementation method.

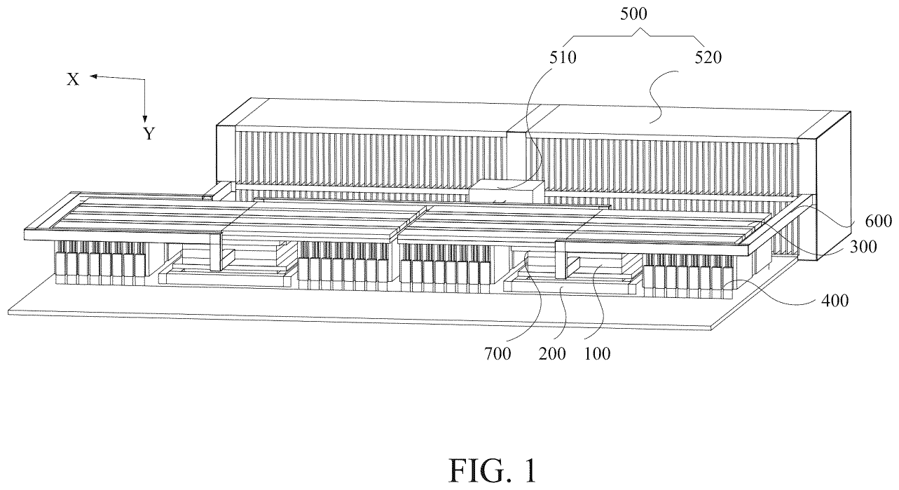

Referring to FIG. 1, a motherboard cooling system according to an embodiment of the present disclosure includes a cooling plate structure 100, a heat diffusion structure 300, a heat dissipation structure 500, and a connection structure 600.

The cooling plate structure 100 is in thermal contact with the CPU 200, and coolant flows through the cooling plate structure 100 to dissipate heat of the CPU 200. The heat diffusion structure 300 is in thermal contact with the DIMM 400 and the cooling plate structure 100. The heat generated by the DIMM 400 reaches the cooling plate structure 100 through the heat diffusion structure 300. The heat dissipation structure 500 is connected to the cooling plate structure 100, and the heat generated by the CPU 200 and the DIMM 400 is dissipated through the heat dissipation structure 500. The connection structure 600 is connected to the cooling plate structure 100 and the heat dissipation structure 500, respectively. The connection structure 600, the cooling plate structure 100, and the heat dissipation structure 500 cooperatively form a circulation loop.

According to an embodiment, firstly, the heat diffusion structure 300 is in thermal contact with the DIMM 400, and the heat generated by the DIMM 400 can be diffused to the heat diffusion structure 300. In addition, the cooling plate structure 100 is also provided, one side of the cooling plate structure 100 is in contact with the CPU 200, and the other side of the cooling plate structure 100 is in thermal contact with the heat diffusion structure 300. The function of the cooling plate structure 100 is to first collect the heat generated by the CPU 200, and then to transfer the heat of the DIMM 400 to the cooling plate structure 100 through the heat diffusion structure 300, that is, the cooling plate structure 100 is capable of collecting the heat of the DIMM 400 and the CPU 200 at the same time. Moreover, the cooling plate structure 100 and the heat dissipation structure 500 form a closed circulation loop through the connection structure 600. The heat of the DIMM 400 and the CPU 200 absorbed by the cooling plate structure 100 enters the coolant, and then is transferred to the heat dissipation structure 500 through the coolant. The heat dissipation between the coolant and the air is achieved through the heat dissipation structure 500, and the cooled coolant flows into the next liquid cycle again.

Through the aforementioned configurations, the motherboard cooling system can integrate the cooling of the CPU 200 and the cooling of the DIMM 400, and dissipate heat cooperatively through the cooling plate structure 100 and the heat dissipation structure 500, thereby omitting the liquid cooling pipeline and the interface, and can minimize the risk of leakage.

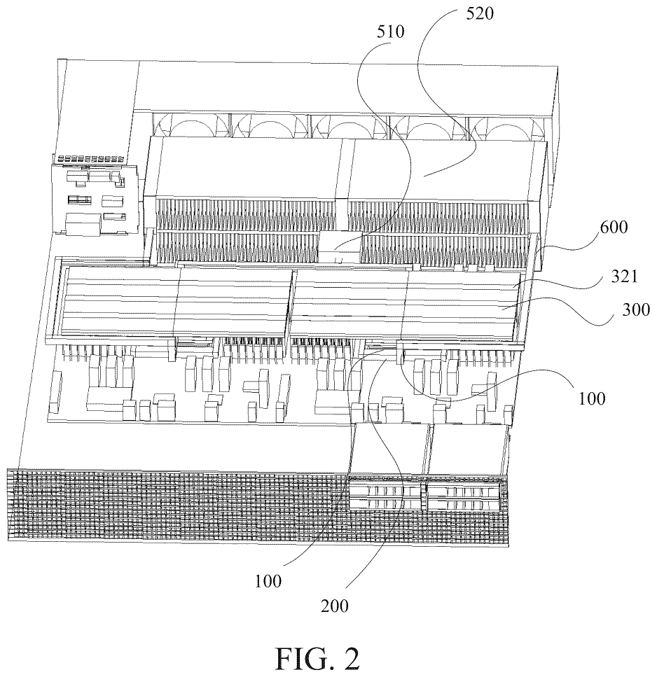

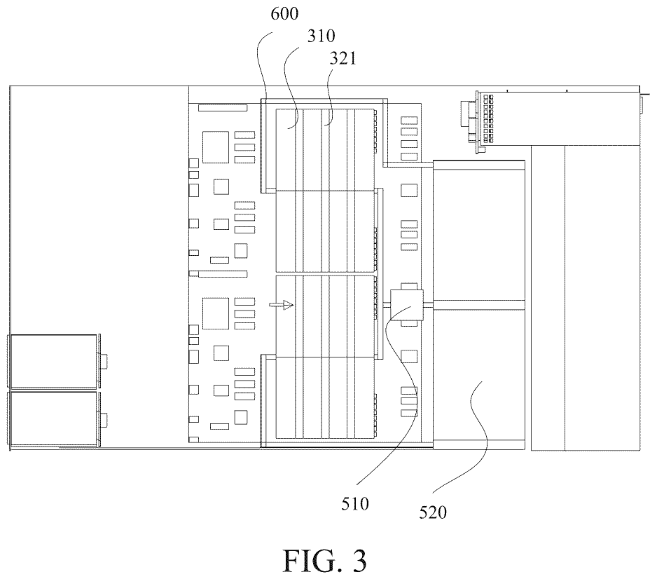

Further, as shown in FIG. 1 to FIG. 3, the heat dissipation structure 500 includes a pump body 510 and a heat sink 520. The pump body 510 is in communication with the cooling plate structure 100 through the connection structure 600, and the coolant flows in the circulation loop under driving of the pump body 510. The heat sink 520 is in communication with the pump body 510 through the connection structure 600, and the coolant flows through the heat sink 520 under driving of the pump body 510 to dissipate heat. In one embodiment, the heat dissipation structure 500 includes the pump body 510 and the heat sink 520. One end of the pump body 510 is in communication with the cooling plate structure 100, and the other end of the pump body 510 is in communication with the heat sink 520. The pump body 510 is configured to drive the coolant in the cooling plate structure 100 to flow into the heat sink 520, and the heat sink 520 dissipates heat. Furthermore, the heat sink 520 is in communication with the cooling plate structure 100 through another connection structure 600, such that the coolant after the cooled by the heat sink 520 can flow into the cooling plate structure 100, and then the next cooling flow can be carried out to complete a closed circulation loop.

Specifically, the heat sink 520 includes a plurality of heat dissipation fins, which are main components of the heat sink 520 and is usually made of metal materials, such as aluminum, copper or copper-aluminum composite materials. The heat dissipation fins have a large surface area and can improve the heat dissipation efficiency by increasing the contact area with the air. The shapes and arrangements of the heat dissipation fins can be varied. In one embodiment, the heat dissipation fins are fin-shaped. The densely arranged heat dissipation fins can quickly absorb the heat generated by the CPU 200 and dissipate it into the air.

In one embodiment, the motherboard cooling system also includes a first heat conduction layer 700. One side of the first heat conduction layer 700 is in contact with the cooling plate structure 100, and the other side of the first heat conduction layer 700 is in contact with the heat diffusion structure 300. The first heat conduction layer 700 is an interface material, which can fill a gap between the heat diffusion structure 300 and the cooling plate structure 100, reduce the contact thermal resistance, and improve the heat transfer efficiency. The first heat conduction layer 700 may be a thermal conductive silicone grease, thermal conductive silicone sheet, thermal conductive gel or phase change thermal conductive material. The aforementioned thermal conductive materials usually have good thermal conductivity, insulation and chemical stability, and can be selected according to actual needs.

Specifically, as shown in FIG. 5, the cooling plate structure 100 includes a plate body 110 and at least one fin 120. The plate body 110 is provided with a receiving cavity, and the plate body 110 is configured to be in thermal contact with the CPU 200 and the heat diffusion structure 300. The at least one fin 120 is provided in the receiving cavity, and the coolant flows in the at least one fin 120. The main structure of the cooling plate structure 100 is the plate body 110, the plate body 110 is usually made of a metal material, such as aluminum, copper, etc., and the aforementioned material has good thermal conductivity. One side of the plate body 110 is in thermal contact with the heat diffusion structure 300, and the other side of the plate body 110 is in thermal contact with the CPU 200. The receiving cavity for receiving the flow of the coolant is formed inside the plate body 110. Further, in order to increase the heat exchange area between the coolant and the plate body 110 and improve the heat exchange efficiency, the at least one fin 120 is provided in the receiving cavity of the cooling plate structure 100. The at least one fin 120 can increase the contact area with the coolant. When the heat of the coolant is transferred to the at least one fin 120, more coolant can be in contact with surfaces of fins 120, thereby accelerating the speed of convection and transferring the heat to the coolant faster to be taken away. On the other hand, the at least one fin 120 are usually made of materials with good thermal conductivity, such as aluminum, copper, etc., which can effectively transfer the heat on a surface of the CPU 200 and a surface of the heat diffusion structure 300 to various parts of at least one fin 120, thereby increasing the effective area of heat dissipation, and improving the overall heat transfer efficiency.

Further, the at least one fin 120 includes a plurality of the fins. The plurality of fins 120 are arranged in parallel and equally spaced. Each fin 120 is a straight fin. The straight fin has a simple structure, a regular shape, and is arranged in a straight line, which is relatively easy to implement, whether by stamping, rolling, extruding or other processing techniques. This simple structure makes the mold design and manufacturing difficulty in the production process lower, the production efficiency higher, and the cost relatively low. Moreover, the fin 120 can effectively increase the heat dissipation area, thereby strengthening the heat exchange process. A surface of the fin 120 is in sufficient contact with the coolant, which is conducive to the heat transfer to the surrounding environment by convection. In some application scenarios where the heat dissipation requirements are not extremely stringent, the fin 120 can provide sufficient heat dissipation capacity. In addition, compared with some fins 120 with complex shapes (such as sawtooth fins, corrugated fins, etc.), the surface of the fin 120 are relatively smooth, and the coolant flows smoothly when flowing through the fin 120, and the resistance generated is small. Therefore, the adoption of the fin 120 in one embodiment can reduce noise.

Specifically, the heat diffusion structure 300 includes a heat diffusion main body 310 and a heat conduction portion 320. The heat diffusion main body 310 is configured to be in thermal contact with the DIMM 400 and the cooling plate structure 100. The heat conduction portion 320 is provided on the heat diffusion main body 310. The heat conduction portion 320 is configured to transfer the heat generated by the DIMM 400 to the cooling plate structure 100. In one embodiment, the heat diffusion structure 300 includes a heat diffusion main body 310. The heat diffusion main body 310 is configured to be in close contact with the heat-generating component DIMM 400. The heat diffusion main body 310, made of high thermal conductivity materials such as copper and aluminum, has good thermal conductivity, thus it can absorb the heat generated by the DIMM 400 quickly. Since the heat diffusion main body 310 is in contact with the DIMM 400 over a large area, the heat transfer area is increased, such that the heat can be transferred from the DIMM 400 to the heat diffusion main body 310 more efficiently. The heat conduction portion 320 is connected to the heat diffusion main body 310, and the heat conduction portion 320 is capable of receiving the heat of the heat diffusion main body 310 and transfer the heat efficiently, and finally transfer the heat to the cooling plate structure 100, and the cooling plate structure 100, the pump body 510 and the heat sink 520 are used for heat dissipation.

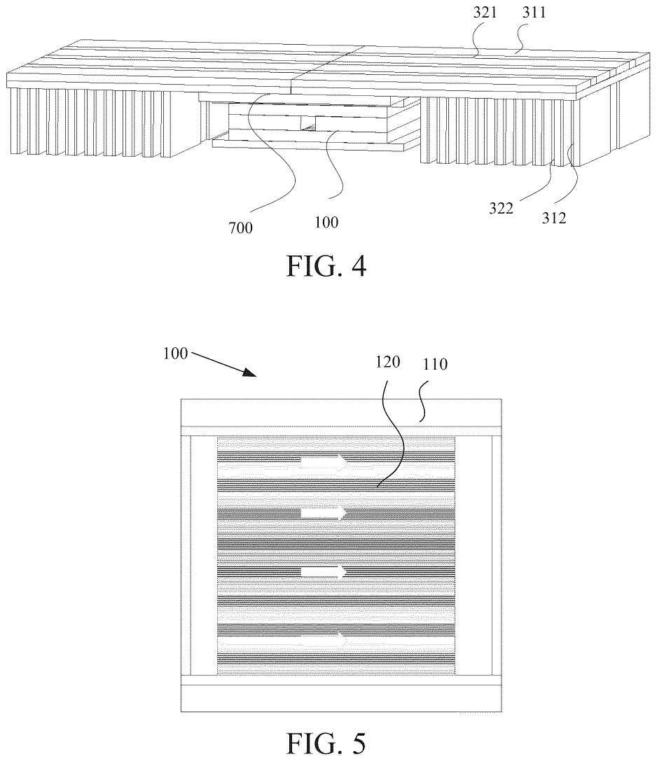

Further, as shown in FIG. 4, an insertion space is formed between adjacent DIMMs 400, and the heat diffusion main body 310 includes a first main body 311 and a plurality of second main bodies 312. The first main body 311 is arranged along the first direction, and the first main body 311 is in thermal contact with the cooling plate structure 100. The plurality of second main bodies 312 are arranged along the second direction. The plurality of second main bodies 312 are connected to the first main body 311 and inserted in the insertion space, so as to be in thermal contact with the DIMM 400. The first direction and the second direction are arranged crosswise. In one embodiment, the heat diffusion main body 310 includes a first main body 311 and a second main body 312. The first main body 311 is arranged along the first direction, and the second main body 312 is arranged along the second direction. The first direction and the second direction intersect each other. Specifically, the first direction and the second direction are perpendicular to each other. After the first main body 311 and the second main body 312 are connected to each other, the second main body 312 can be inserted into the insertion space, such that the heat generated by the DIMM 400 is transferred to the first main body 311 by the second main body 312. The first main body 311 and the second main body 312 have good thermal conductivity, thus the heat generated by the DIMM 400 can be quickly absorbed to the heat diffusion main body 310 of, and then transferred to the heat conduction portion 320.

Specifically, the heat conduction portion 320 also includes a second heat conduction layer 322 arranged on a surface of each second main body 312, and the second heat conduction layer 322 is in contact with the DIMM 400. In one embodiment, the second heat conduction layer 322 is provided on a surface of the second main body 312, specifically on two side surfaces of the second main body 312, and the second heat conduction layer 322 is in thermal contact with the surface of the DIMM 400 for heat conduction. The second heat conduction layer 322 is the same as the first heat conduction layer 700 and is also made of an interface material to fill the gap between the heat diffusion structure 300 and the DIMM 400, so as to reduce the contact thermal resistance and improve the heat transfer efficiency. The second heat conduction layer 322 may be a thermal conductive silicone grease, thermal conductive silicone sheet, thermal conductive gel or phase change thermal conductive material. The aforementioned thermal conductive materials usually have good thermal conductivity, insulation and chemical stability, and can be selected according to actual needs.

Then, specifically, the heat conduction portion 320 includes a plurality of heat pipes 321. Each of the heat pipes 321 has an evaporation end and a condensation end. The evaporation end is in thermal contact with second heat conduction layer 322, and the condensation end is in thermal contact with the cooling plate structure 100. The heat pipe 321 is configured for heat conduction and heat transfer, and the heat pipe 321 has an evaporation section and a condensation section. The evaporation section of the heat pipe 321 is in contact with the second heat conduction layer 322 on the DIMM 400. When the DIMM 400 generates heat, the heat is transferred to the evaporation section of heat pipe 321. Since an interior of the heat pipe 321 is sealed and is filled with an appropriate amount of working liquid (such as common water, ethanol, ammonia, etc., different working liquids are suitable for different temperature ranges and working conditions), after the working liquid in the evaporation section absorbs heat, the temperature thereof rises, and the working liquid evaporates due to the heat and turns into steam. Due to the low density of the steam, it will quickly flow to the other end (condensation section) of the heat pipe 321. In the condensation section, the steam encounters the pipe wall with a lower temperature, releases heat and condenses into liquid. Under the action of gravity or capillary force, the condensed liquid flows back to the evaporation section, absorbs heat again and evaporates, and the cycle repeats, quickly transferring heat from the heat source to a farther place to achieve heat diffusion.

According to another embodiment, a server is provided, including a chassis and the aforementioned motherboard cooling system. The motherboard cooling system is arranged in the chassis to cool the CPU 200 and the DIMM 400.

In the aforementioned motherboard cooling system, the cooling plate structure 100 is in contact with the CPU 200, and the cooling plate structure 100 is capable of collecting the heat generated by the CPU 200. Furthermore, the cooling plate structure 100 is in contact with the heat diffusion structure 300, and the heat diffusion structure 300 is in contact with the DIMM 400, that is, the cooling plate structure 100 is capable of absorbing the heat generated by the DIMM 400 through the heat diffusion structure 300. Finally, the cooling plate structure 100 is capable of absorbing the heat generated by the CPU 200 and the DIMM 400 in an integrated manner. Moreover, the cooling plate structure 100 and the heat dissipation structure 500 form a closed circulation loop through the connection structure 600. The heat of the DIMM 400 and the CPU absorbed by the cooling plate structure 100 enters the coolant, and then enters the heat dissipation structure 500 through the coolant. The heat dissipation between the coolant and the air is completed through the heat dissipation structure 500, and the cooled coolant flows into the next liquid cycle again. The aforementioned motherboard cooling system is placed in the server, which can solve the heat dissipation problem of DIMM and CPU in an integrated manner. The two can dissipate heat cooperatively, and can be realized through fewer connection structures and interfaces, reducing the risk of leakage of the cooling system and increasing its reliability. In addition, the closed-loop motherboard cooling system in one embodiment is provided in the server, which can achieve better heat dissipation effect compared with fan cooling. Moreover, in one embodiment, by providing the heat diffusion structure 300, the heat diffusion structure 300 is in thermal contact with the cooling plate structure 100 and the DIMM 400 respectively, such that the heat diffusion structure 300 can be used to modularize the heat dissipation function of the DIMM 400, and no additional liquid cooling pipes are required.

The technical features of the aforementioned embodiments may be combined arbitrarily. To simplify the description, not all the possible combinations of the technical features in the aforementioned embodiments are described. However, all of the combinations of these technical features should be considered as within the scope of the present disclosure, as long as such combinations do not contradict with each other.

The above embodiments merely illustrate several embodiments of the present disclosure, and the description thereof is specific and detailed, but it shall not be constructed as limiting the scope of the disclosure. It should be noted that, for a person of ordinary skill in the art, several variations and improvements may be made without departing from the concept of the present disclosure, and these are all within the protection scope of the present disclosure. Therefore, the protection scope of the present disclosure shall be subject to the appended claims.

What is claimed is:

1. A motherboard cooling system, comprising:
a cooling plate structure in thermal contact with a CPU, and a coolant flowing through the cooling plate structure to dissipate heat of the CPU;
a heat diffusion structure in thermal contact with a DIMM and the cooling plate structure, and heat generated by the DIMM reaching the cooling plate structure through the heat diffusion structure;
a heat dissipation structure connected to the cooling plate structure, and the heat generated by the CPU and the DIMM being dissipated through the heat dissipation structure; and
a connection structure connected to the cooling plate structure and the heat dissipation structure, respectively, and the connection structure, the cooling plate structure, and the heat dissipation structure cooperatively forming a circulation loop.

2. The motherboard cooling system according to claim 1, wherein the heat dissipation structure comprises:
a pump body in communication with the cooling plate structure through the connection structure, and the coolant flowing in the circulation loop under driving of the pump body; and
a heat sink in communication with the pump body through the connection structure, and the coolant flowing through the heat sink under driving of the pump body to dissipate heat.

3. The motherboard cooling system according to claim 1, further comprising a first heat conduction layer, one side of the first heat conduction layer being in thermal contact with the cooling plate structure, and another side of the first heat conduction layer being in thermal contact with the heat diffusion structure.

4. The motherboard cooling system according to claim 1, wherein the cooling plate structure comprises:
a plate body provided with a receiving cavity, and the plate body being configured to be in thermal contact with the CPU and the heat diffusion structure; and
at least one fin arranged in the receiving cavity, and the coolant flowing in the fin.

5. The motherboard cooling system according to claim 4, wherein the at least one fin comprises a plurality of the fins, each fin is a straight fin, and the plurality of the fins are arranged in parallel and equally spaced.

6. The motherboard cooling system according to claim 1, wherein the heat diffusion structure comprises:
a heat diffusion main body configured to be in thermal contact with the DIMM and the cooling plate structure; and
a heat conduction portion provided on the heat diffusion main body, and the heat conduction portion being configured to transfer heat generated by the DIMM to the cooling plate structure.

7. The motherboard cooling system according to claim 6, wherein an insertion space is formed between adjacent DIMMs, and the heat diffusion main body comprises:
a first main body arranged along a first direction and in thermal contact with the cooling plate structure; and
a plurality of second main bodies arranged along a second direction, the plurality of second main bodies being connected to the first main body, and each of the plurality of second main bodies being inserted in the insertion space and in thermal contact with the DIMM;
wherein the first direction and the second direction are arranged crosswise.

8. The motherboard cooling system according to claim 7, wherein the heat conduction portion comprises:
a second heat conduction layer arranged on a surface of each second main body, and the second heat conduction layer being in thermal contact with the DIMM.

9. The motherboard cooling system according to claim 8, wherein the heat conduction portion further comprises:
a plurality of heat pipes, each of the plurality of heat pipes having an evaporation end and a condensation end, the evaporation end being in thermal contact with the second heat conduction layer, and the condensation end being in thermal contact with the cooling plate structure.

10. A server, comprising a chassis and the motherboard cooling system according to claim 1 arranged in the chassis to cool the CPU and the DIMM.
